(19) United States
(12) Patent Application Publication
(10) Pub. No.: US 2014/0002777 A1
(43) Pub. Date: Jan. 2, 2014

(54) REFLECTIVE LIQUID CRYSTAL DISPLAYS AND METHODS OF FABRICATING THE SAME

(71) Applicant: Electronics and Telecommunications Research Institute, (US)

(72) Inventors: Gi Heon KIM, Daejeon (KR); Hojun Ryu, Seoul (KR)

(73) Assignee: Electronics and Telecommunications Research Institute, Daejeon (KR)

(21) Appl. No.: 13/738,593

(22) Filed: Jan. 10, 2013

(30) Foreign Application Priority Data
Jun. 29, 2012 (KR) 10-2012-0071078

(51) Int. Cl. G02F 1/1333; H01L 33/00

(52) U.S. Cl. CPC G02F 1/133362; H01L 33/005
USPC 349/106; 438/30; 349/113

(57) ABSTRACT

Provided are reflective liquid crystal displays and methods of fabricating the same. the displays may include may include a first substrate, a reflective layer on the first substrate, a first electrodes on the reflective layer, a first insulating layer on the first electrodes, a second substrate facing the first substrate, a second electrode on the second substrate, a second insulating layer on the second electrode, and a liquid crystal layer between the first insulating layer and the second insulating layer. The second insulating layer has concavo-convex portions, which may be formed in contact with the liquid crystal layer to improve linearity of an incident light propagating from the second substrate toward the reflective layer and a reflected light propagating from the reflective layer toward the second substrate.

### CROSS-REFERENCE TO RELATED APPLICATIONS

This U.S. non-provisional patent application claims priority under 35 U.S.C. §119 to Korean Patent Application No. 10-2012-0071078, filed on Jun. 29, 2012, in the Korean Intellectual Property Office, the entire contents of which are hereby incorporated by reference.

### BACKGROUND OF THE INVENTION

This disclosure relates to a liquid crystal display and a method of fabricating the same, and in particular, to reflective liquid crystal displays and methods of fabricating the same.

Display technology becomes more and more important, due to the advent of the information era. Accordingly, there have been suggested flat panel displays, such as liquid crystal display (LCD), plasma display panel (PDP), and organic light-emitting display (OLED). For the liquid crystal display, a white light generated from a backlight unit may propagate through two polarizing plates, a liquid crystal layer, and a color filter layer, thereby displaying a specific color determined by the color filter layer. The liquid crystal display has been widely used for mobile terminals, laptops, monitors, or television, owing to its low voltage operation.

However, a part of the white light passing through the polarizing plates and the color filter layer is used to display image, and thus, the liquid crystal display suffers from low optical efficiency. In addition, the use of the backlight unit may lead to an increase in power consumption of the liquid crystal display.

Alternatively, there has been proposed a reflective liquid crystal display without the backlight unit. For all that, owing to bad linearity of incident and/or reflected lights passing the liquid crystal layer, the conventional reflective liquid crystal display also suffers from low optical efficiency.

### SUMMARY

Example embodiments of the inventive concept provide a reflective liquid crystal display capable of improving optical efficiency.

Other example embodiments of the inventive concept provide a reflective liquid crystal display capable of reducing a fabrication cost of a panel.

Still other example embodiments of the inventive concept provide a reflective liquid crystal display capable of reducing power consumption.

According to example embodiments of the inventive concepts, a reflective liquid crystal display may include a first substrate, a reflective layer on the first substrate, a first electrodes on the reflective layer, a first insulating layer on the first electrodes, a second substrate facing the first substrate, a second electrode on the second substrate, a second insulating layer on the second electrode, and a liquid crystal layer between the first insulating layer and the second insulating layer. The second insulating layer has concavo-convex portions, which may be formed in contact with the liquid crystal layer to improve linearity of an incident light propagating from the second substrate toward the reflective layer and a reflected light propagating from the reflective layer toward the second substrate.

In example embodiments, the concavo-convex portions have a hemi-spherical shape and/or a pyramid shape.

In example embodiments, the device may further include color filters provided between the reflective layer and the first electrodes.

In example embodiments, the device may further include a first planarization layer provided between the color filters and the first electrodes.

In example embodiments, the device may further include third insulating layers provided between the first planarization layer and the reflective layer to separate the color filters from each other.

In example embodiments, the device may further include thin-film transistors provided between the third insulating layer and the first planarization layer and connected to the first electrodes via a contact electrode penetrating the first planarization layer.

In example embodiments, the device may further include partition walls provided between the first and second insulating layers to divide the liquid crystal layer into a plurality of sub pixels corresponding to the first electrodes.

In example embodiments, each of the sub pixels of the liquid crystal layer may contain a coloring material capable of displaying a corresponding one of the three primary colors or the three primary lights.

In example embodiments, the device may further include color filters provided between the upper electrode and the upper substrate, and a second planarization layer covering the color filters and the upper substrate.

In example embodiments, the liquid crystal layer may contain a black coloring material.

According to example embodiments of the inventive concepts, a method of fabricating a reflective liquid crystal display may include forming a reflective layer on a first substrate, forming a first electrode on the reflective layer, forming a first insulating layer on the first electrode, forming a second electrode on a second substrate facing the first substrate, forming a second insulating layer on the second electrode to have concavo-convex portions, forming a liquid crystal layer on one of the first and second substrates, and jointing the first and second substrates.

In example embodiments, the concavo-convex portions may be formed using an embossing process.

In example embodiments, the embossing process may include printing the concavo-convex portions with an engraving roll and/or an engraving sheet.

In example embodiments, the method may further include forming a third insulating layer on the reflective layer, forming a thin-film transistor on the third insulating layer, forming a first planarization layer on the thin-film transistor and the third insulating layer, patterning the first planarization layer to form a contact hole exposing a top surface of the thin-film transistor, and forming a contact electrode in the contact hole.

In example embodiments, the method may further include forming color filters on the reflective layer.

In example embodiments, the method may further include forming partition walls on one of the first and second insulating layers between the first electrodes.

In example embodiments, the method may further include before the forming of the second electrode, forming color filters on the second substrate, and forming a second planarization layer on the color filters and the second substrate.

In example embodiments, the method may further include forming partition walls on the first insulating layer.

In example embodiments, the forming of the liquid crystal layer may include dripping a liquid crystal material between the partition walls.

In example embodiments, the liquid crystal layer may contain coloring materials allowing each of sub pixels, which may be defined by the first electrodes, to display a corresponding one of the three primary colors or the three primary lights.

### BRIEF DESCRIPTION OF THE DRAWINGS

Example embodiments will be more clearly understood from the following brief description taken in conjunction with the accompanying drawings. FIGS. 1 through 32 represent non-limiting, example embodiments as described herein.

FIG. 1 is a sectional view illustrating a reflective liquid crystal display according to a first embodiment of the inventive concept.

FIGS. 2 and 3 are sectional views schematically showing propagation of lights incident to and reflected from a liquid crystal layer and a second insulating layer of FIG. 1.

FIGS. 4 through 15 are sectional views illustrating a method of fabricating a reflective liquid crystal display according to the first embodiment of the inventive concept.

FIG. 16 is a sectional view illustrating a reflective liquid crystal display according to a second embodiment of the inventive concept.

FIGS. 17 through 25 are sectional views illustrating a method of fabricating a reflective liquid crystal display according to the second embodiment of the inventive concept.

FIG. 26 is a sectional view illustrating a reflective liquid crystal display according to a third embodiment of the inventive concept.

FIGS. 27 through 32 are sectional views illustrating a method of fabricating a reflective liquid crystal display according to the third embodiment of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

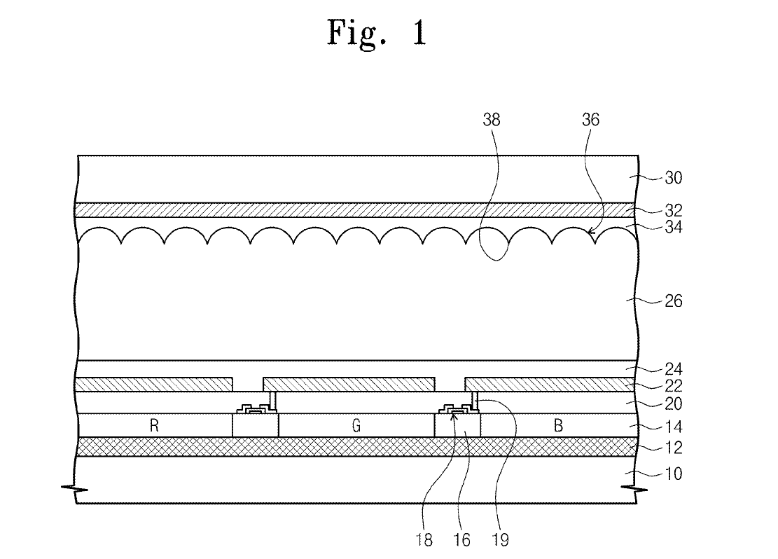

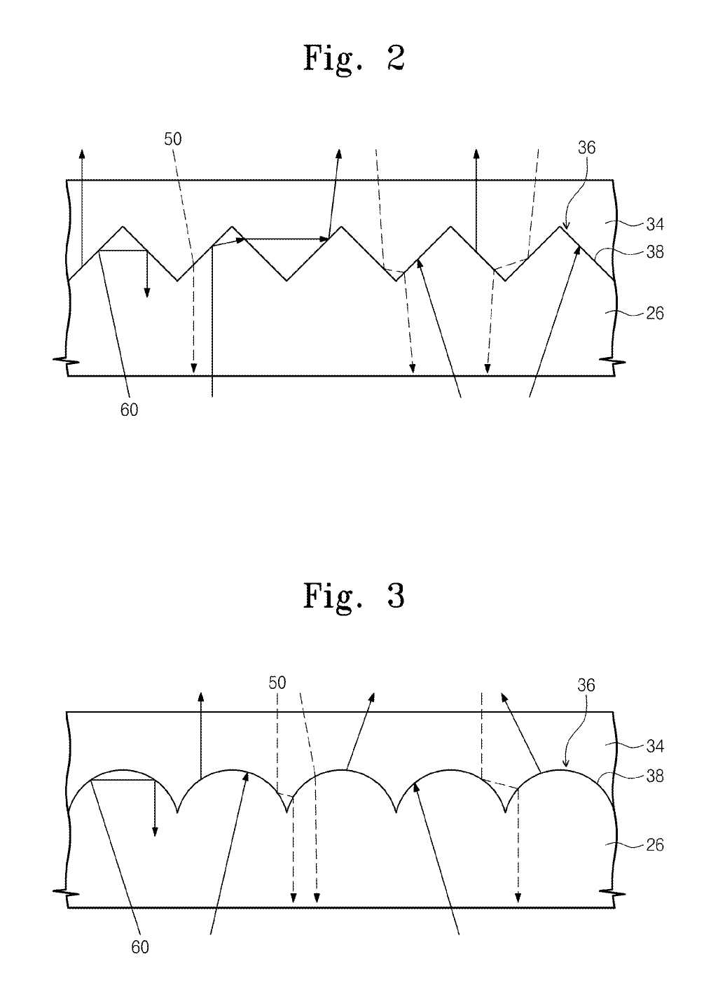

FIG. 1 is a sectional view illustrating a reflective liquid crystal display according to a first embodiment of the inventive concept. FIGS. 2 and 3 are sectional views schematically showing propagation of lights incident to and reflected from a liquid crystal layer and a second insulating layer of FIG. 1.

Referring to FIGS. 1 through 3, according to a first embodiment of the inventive concept, a reflective liquid crystal display may include a lower substrate 10, an upper substrate 30 facing the lower substrate 10, and a liquid crystal layer 26 between the upper substrate 30 and the lower substrate 10.

Each of the lower substrate 10 and the upper substrate 30 may be configured to include a transparent glass layer and/or a transparent plastic layer. The liquid crystal layer 26 may include nematic liquid crystal molecules mixed with a black coloring material (not shown). In example embodiments, pigment and/or dye may be used for the black coloring material. The liquid crystal layer 26 may be configured to determine refraction and absorption of an incident light 50 transmitted from the upper substrate 30 and a reflected light 60 reflected by a reflective layer 12.

In example embodiments, an electric field may be selectively generated between lower electrodes 22 and an upper electrode 32, which may be provided on the lower substrate 10 and the upper substrate 30, respectively. In the case of the presence of the electric field, the incident light 50 and the reflected light 60 may be transmitted through the liquid crystal layer 26. In the case of the absence of the electric field, the incident light 50 and the reflected light 60 may be absorbed by the liquid crystal layer 26.

In addition to the reflective layer 12, a layer of color filters 14, a third insulating layer 16, a first planarization layer 20, thin-film transistors 18, the lower electrodes 22, and a first insulating layer 24 may be disposed between the liquid crystal layer 26 and the lower substrate 10.

The reflective layer 12 may reflect the incident light 50 transmitted through the upper substrate 30 and the liquid crystal layer 26. In example embodiments, the reflective layer 12 may include a highly reflective material, such as aluminum (Al) and/or silver (Ag).

The layer of color filters 14 may be configured to colorize the incident light 50 and the reflected light 60. For example, the layer of color filters 14 may be configured to include a RGB color filter array for displaying the three primary lights (e.g., red, green, and blue) or a CMY color filter array for displaying the three primary colors (e.g., cyan, magenta, and yellow). The third insulating layer 16 may be disposed between the color filters. The third insulating layer 16 may include a dielectric layer.

The thin-film transistors 18 may be disposed on the third insulating layer 16. Each of the thin-film transistors 18 may be connected to a corresponding one of the lower electrodes 22 via a contact electrode 19. The thin-film transistors 18 may be configured to control electric connection of a bias voltage applied to the lower electrodes 22. Although not shown, each of the thin-film transistors 18 may include a gate line, a gate insulating layer provided on the gate line, an active pattern provided on the gate insulating layer, source and drain electrodes spaced apart from each other on the active pattern, and a data line connected to the source. The contact electrode 19 may be connected to the drain electrode.

The first planarization layer 20 may cover the thin-film transistors 18 and the layer of color filters 14. The first planarization layer 20 may be configured to prevent impurities in the layer of color filters 14 from being diffused into the liquid crystal layer 26. Due to the presence of the first planarization layer 20, the lower electrodes 22 may be formed to be coplanar with each other, and this enables to maintain uniformly a cell gap between the lower electrodes 22 and the upper electrode 32. In example embodiments, the first planarization layer 20 may include a transparent polymer (e.g., polymethylmethacrylate (PMMA)) and/or a resist layer.

Each of the lower electrodes 22 may be disposed to face a corresponding one of the color filters 14, thereby serving as a pixel electrode. Each of the lower electrodes 22 may have an area equivalent to or larger than that of the corresponding one of the color filters 14. The lower electrodes 22 may include at least one transparent conductive material. For example, the lower electrodes 22 may include at least one of an indium-tin-oxide (ITO) layer, an indium-zinc-oxide (IZO) layer, silver nanowires, carbon nanotubes, a grapheme layer, a PEDOT:PSS layer, a polyaniline layer, or a polythiophene layer.

The first insulating layer 24 may be formed to cover the lower electrodes 22 and the first planarization layer 20, thereby serving as a passivation layer. The first insulating layer 24 may include a transparent organic material (such as, polyimide, polyacrylate, epoxy, polyvinyl alcohol, parylene, polystyrene, polyacetate, polyvinylpyrrolidone, fluorinated polymer, or polyvinylchloride). Alternatively, the first insulating layer 24 may include a transparent inorganic material (such as, a silicon oxide layer, a silicon nitride layer, a silicon oxynitride layer, a silicon carbide layer, a silicon oxycarbide layer).

The upper electrode 32 and a second insulating layer 34 may be provided between the liquid crystal layer 26 and the upper substrate 30. One surface of the upper substrate 30 may be entirely covered with the upper electrode 32. The upper electrode 32 may serve as a common electrode, which may be used to generate an electric field along with the pixel electrode applied with a bias voltage. In example embodiments, the upper electrode 32 may include a transparent conductive material, similar to the lower electrodes 22.

Similar to the first insulating layer 24, the second insulating layer 34 may include a transparent organic and/or inorganic material. The second insulating layer 34 may include a rough surface 36 in contact with the liquid crystal layer 26. In example embodiments, the rough surface 36 may include concavo-convex portions 38 regularly formed on a surface of the second insulating layer 34. Each of the concavo-convex portions 38 may be formed to have a hemi-spherical shape and/or a pyramid shape.

The rough surface 36 may contribute to improve transmittance and/or linearity of the incident light 50. The incident light 50 may propagate from the upper substrate 30 toward the reflective layer 12. The incident light 50 may be transmitted through or refracted from the second insulating layer 34 to the liquid crystal layer 26. In example embodiments, the incident light 50 may propagate through the rough surface 36 and be transmitted in the liquid crystal layer 26 along a direction normal to the lower substrate 10.

The rough surface 36 may contribute to improve transmittance and/or linearity of the reflected light 60. The reflected light 60 may propagate from the reflective layer 12 toward the upper substrate 30. The reflected light 60 may propagate through the liquid crystal layer 26 and be transmitted into the second insulating layer 34. Due to the presence of the rough surface 36, it is possible to suppress the reflected light 60 from being reflected by the second insulating layer 34. In other words, due to the presence of the rough surface 36, it is possible to increase transmittance of the reflected light 60 to be incident into the second insulating layer 34. In the case where the reflected light 60 is reflected from the concavo-convex portions 38, the reflected light 60 may be transmitted along a direction normal to the liquid crystal layer 26 and the lower substrate 10. Further, the rough surface 36 may enable to increase linearity of the reflected light 60 passing through the second insulating layer 34, and thus, it is possible to prevent the reflected light 60 from being a color mixing problem.

In other words, the reflective liquid crystal display, according to the first embodiment of the inventive concept, can be fabricated to have improved optical efficiency.

A fabricating method of the reflective liquid crystal display, according to the first embodiment of the inventive concept, will be described below.

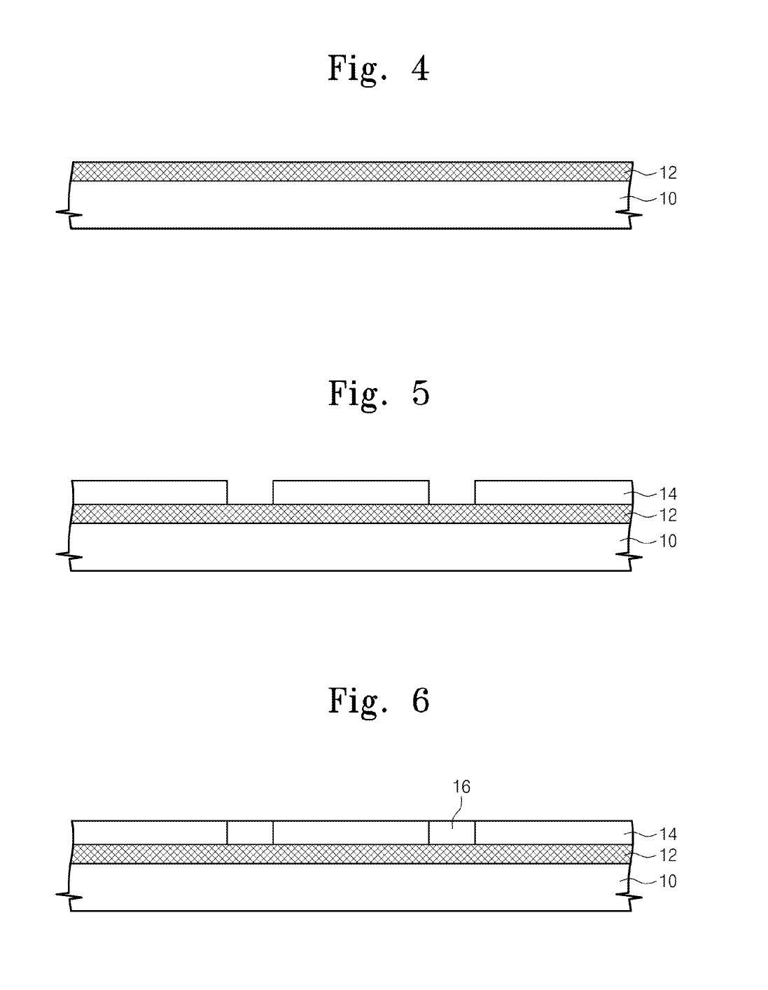

FIGS. 4 through 15 are sectional views illustrating a method of fabricating a reflective liquid crystal display according to the first embodiment of the inventive concept.

Referring to FIG. 4, the reflective layer 12 may be formed on the lower substrate 10. The reflective layer 12 may include a layer contained with silver (Ag) and/or aluminum (Al). The reflective layer 12 may be formed by a physical vapor deposition or a chemical vapor deposition.

Referring to FIG. 5, the layer of color filters 14 may be formed on the reflective layer 12. The color filters 14 may be sequentially printed in accordance with color. The layer of color filters 14 may contain pigment and/or dye formed by a printing method.

Referring to FIG. 6, the third insulating layer 16 may be formed on the reflective layer 12 between the color filters 14. The third insulating layer 16 may include a dielectric or polymer layer formed by a spin-coating method. A rubbing process may be performed to remove a portion of the third insulating layer 16 from a top surface of the layer of color filters 14. Accordingly, the third insulating layer 16 may be formed to fill gaps between the color filters 14, such that the resulting structure has a flat top surface.

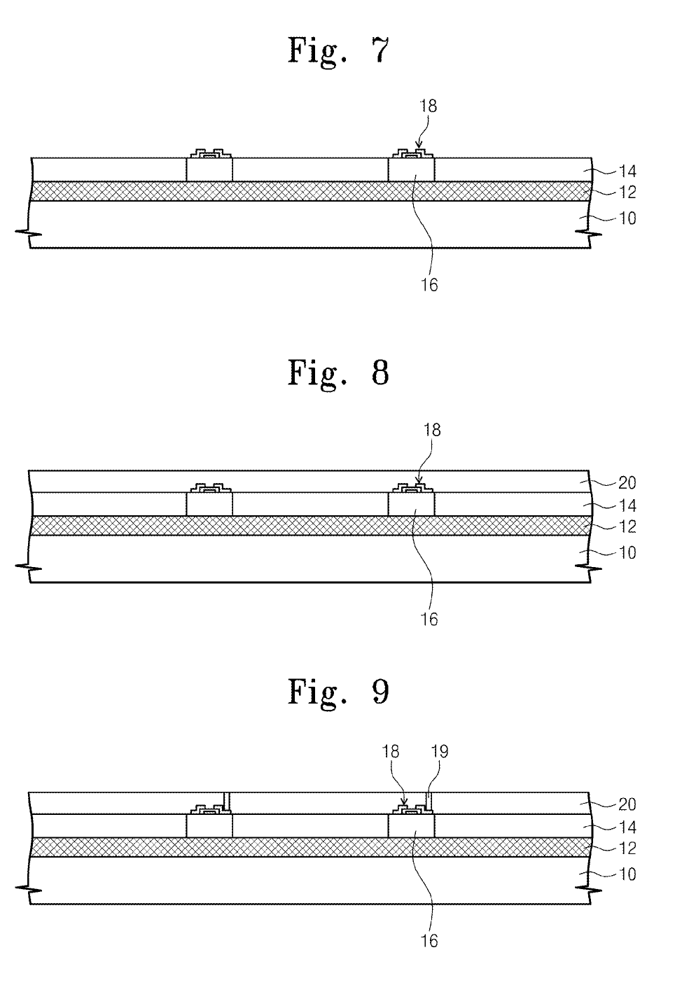

Referring to FIG. 7, the thin-film transistors 18 may be formed on the third insulating layer 16. The formation of the thin-film transistors 18 may include forming a gate line (not shown) on the third insulating layer 16, forming a gate insulating layer (not shown) on the gate line, forming an active layer (not shown) (e.g., of polysilicon) on the gate insulating layer, forming a data line (not shown) to cross the gate line, and then, forming source/drain electrodes (not shown) spaced apart from each other to cover two portions of the active pattern.

Referring to FIG. 8, the first planarization layer 20 may be formed on the thin-film transistors 18 and the layer of color filters 14. The first planarization layer 20 may include a polymer and/or resist layer formed by a spin-coating method.

Referring to FIG. 9, the first planarization layer 20 may be etched to form a contact hole, and the contact electrode 19 may be formed in the contact hole. The contact electrode 19 may be connected to the drain electrode of the thin-film transistors 18.

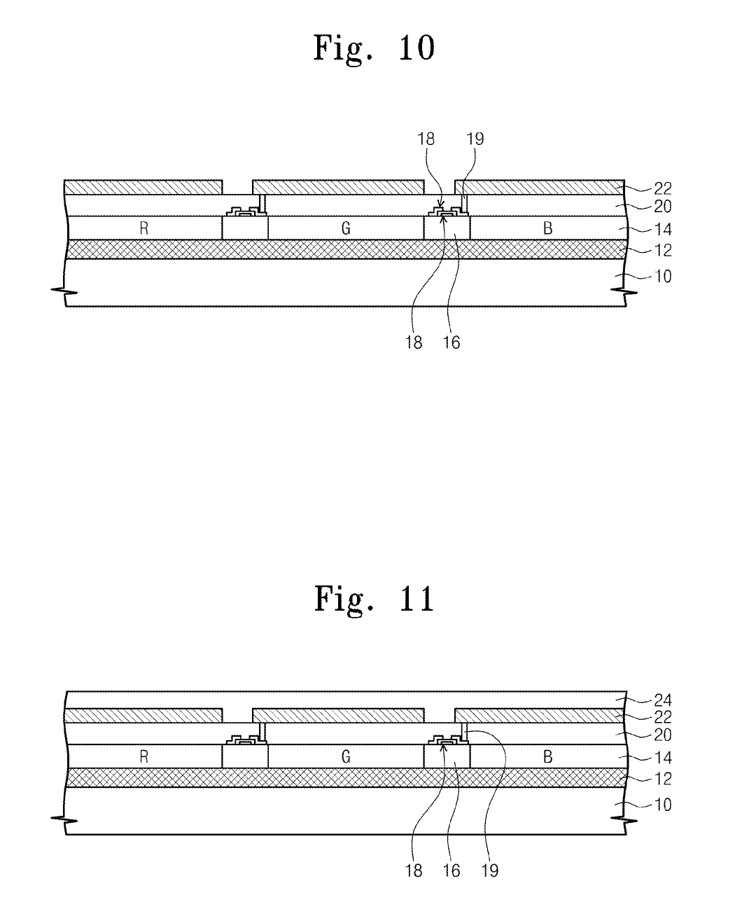

Referring to FIG. 10, the lower electrodes 22 may be formed on the first planarization layer 20. Each of the lower electrodes 22 may be formed to have a shape similar to that the corresponding one of the color filters 14. The lower electrodes 22 may include a transparent metal layer, such as, an indium-tin-oxide (ITO) layer or an indium-zinc-oxide (IZO) layer. The transparent metal layer may be formed by a sputtering process. in other embodiments, the lower electrodes 22 may include a layer of silver nanowires, carbon nanotubes or graphene, which may be formed by a chemical vapor deposition. In still other embodiments, the lower electrodes 22 may include a conductive polymer layer (e.g., of PEDIOT:PSS (Poly 3,4-ethylenedioxythiophene):poly(styrene sulfonate)), polyaniline, or polythiophene). The conductive polymer layer may be formed by a polymer synthesis.

Referring to FIG. 11, the first insulating layer 24 may be formed on the lower electrodes 22 and the first planarization layer 20. The first insulating layer 24 may include a transparent organic material and/or a transparent inorganic material. The transparent organic material and/or the transparent inorganic material may be formed by a spin coating method or a chemical vapor deposition.

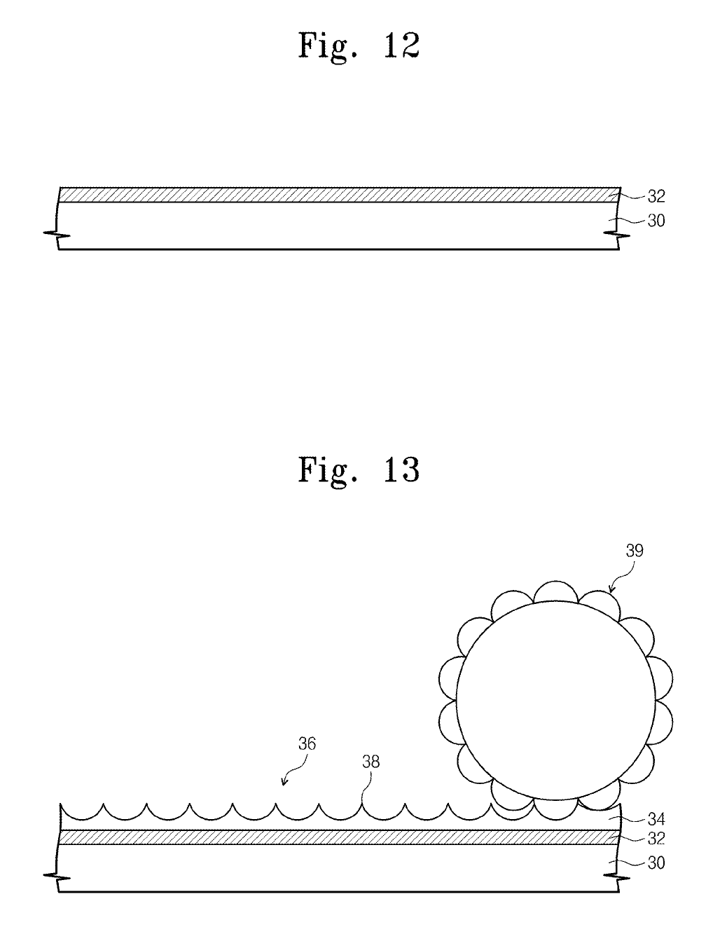

Referring to FIG. 12, the upper electrode 32 may be formed on the upper substrate 30. The upper electrode 32 may include at least one of a transparent metal layer, a silver nanowire layer, a carbon nanotube layer, a graphene layer, a PEDIOT:PSS layer, a polyaniline layer, or a polythiophene layer.

Referring to FIG. 13, the second insulating layer 34 with the rough surface 36 may be formed on the upper electrode 32. The second insulating layer 34 may include a transparent organic material and/or a transparent inorganic material.

In example embodiments, the rough surface 36 of the second insulating layer 34 may be formed by an embossing process. In the embossing process, an engraving roll 39 and/or an engraving sheet may be used to form the concavo-convex portions 38 on a top surface of the second insulating layer 34. For example, in the case where the top surface of the second insulating layer 34 may be pressed by the engraving roll 39, the concavo-convex portions 38 can be easily formed.

Accordingly, it is possible to reduce a cost required to fabricate a panel for the reflective liquid crystal display and to improve fabrication productivity.

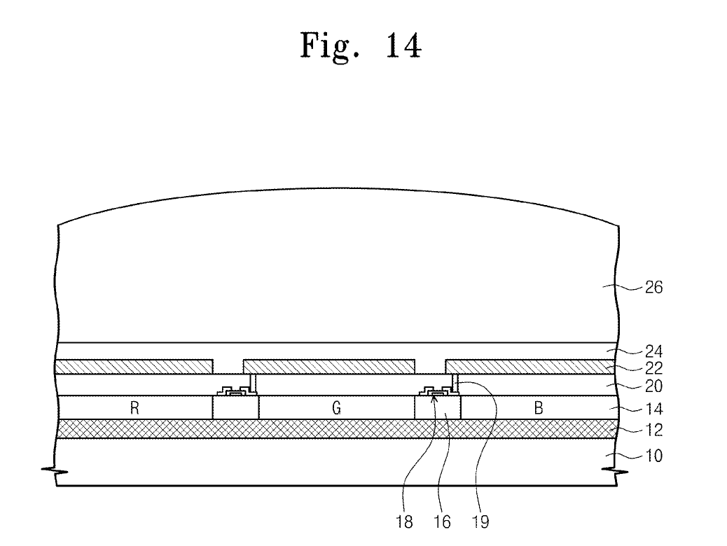

Referring to FIG. 14, the liquid crystal layer 26 may be formed on the lower substrate 10 or the upper substrate 30. The liquid crystal layer 26 may be provided (for example, in a dripping manner) on one of the lower and upper substrates 10 and 30. In example embodiments, an amount of liquid crystal drips may be controlled during the dripping of the liquid crystal layer 26. Although not shown, spacers may be scattered on the liquid crystal layer 26.

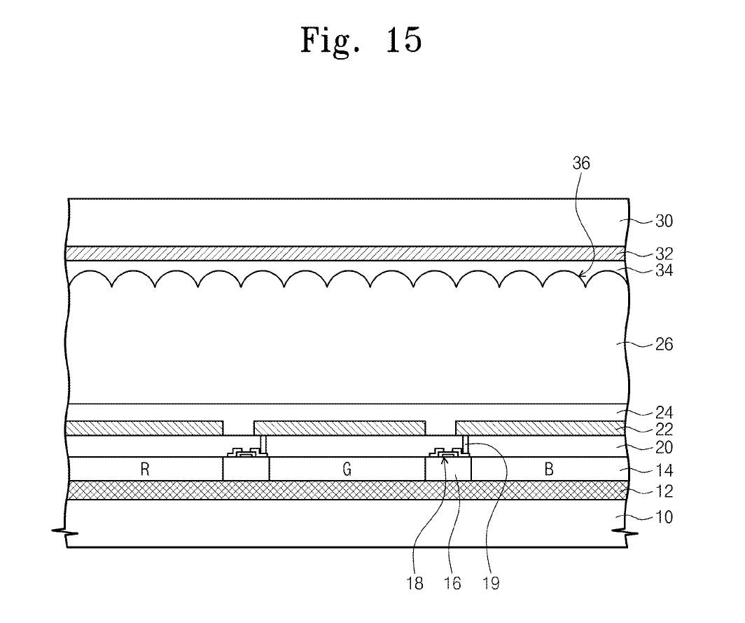

Referring to FIG. 15, the lower and upper substrates 10 and 30 may be jointed with each other. Thereafter, the lower and upper substrates 10 and 30 may be sealed by a sealant (not shown) provided along their sides.

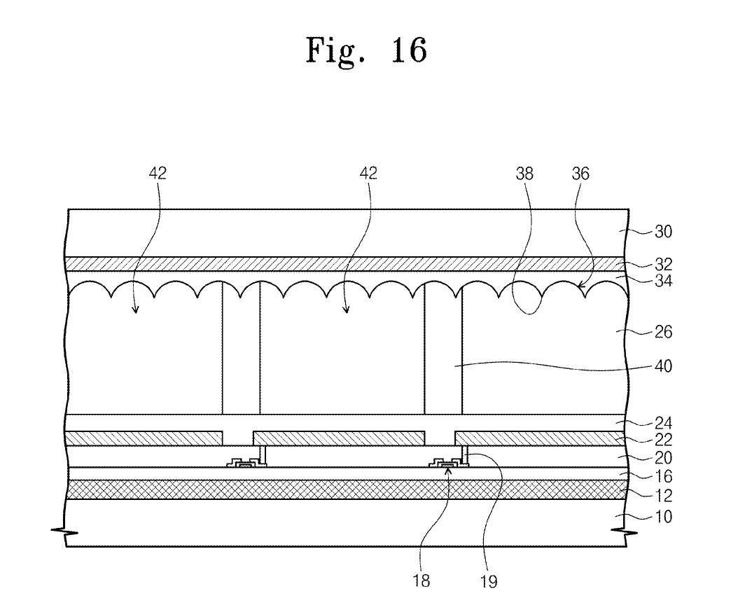

FIG. 16 is a sectional view illustrating a reflective liquid crystal display according to a second embodiment of the inventive concept.

Referring to FIG. 16, according to a second embodiment of the inventive concept, a reflective liquid crystal display may include partition walls 40 interposed between the first insulating layer 24 and the second insulating layer 34 to disunite the liquid crystal layer 26.

The partition walls 40 may be disposed horizontally between the lower electrodes 22 and vertically between the first and second insulating layers 24 and 34. The partition walls 40 may define sub pixels 42 positioned on the lower electrodes 22, respectively. In other words, due to the presence of the partition walls 40, the liquid crystal layer 26 may be divided into the sub pixels 42 separated from each other.

The sub pixels 42 may be classified into a plurality of groups, according to the type of coloring materials contained in therein. The use of the coloring materials enables the sub pixels 42 to display RGB (red, green, and blue) or CMY (cyan, magenta, and yellow).

According to the second embodiment of the inventive concept, the reflective liquid crystal display may be configured not to include the layer of color filters 14. In example embodiments, the third insulating layer 16 may be disposed between the reflective layer 12 and the first planarization layer 20.

The second insulating layer 34 may include the rough surface 36. The rough surface 36 may contribute to improve linearity of the incident light 50 and the reflected light 60. Owing to the presence of the partition walls 40, propagation of the incident and reflected lights 50 and 60 may be confined within each of the sub pixels 42. Accordingly, it is possible to prevent a problem of color mixing from occurring. Furthermore, according to the second embodiment of the inventive concept, the reflective liquid crystal display may have improved optical efficiency.

A fabricating method of the reflective liquid crystal display, according to the second embodiment of the inventive concept, will be described below.

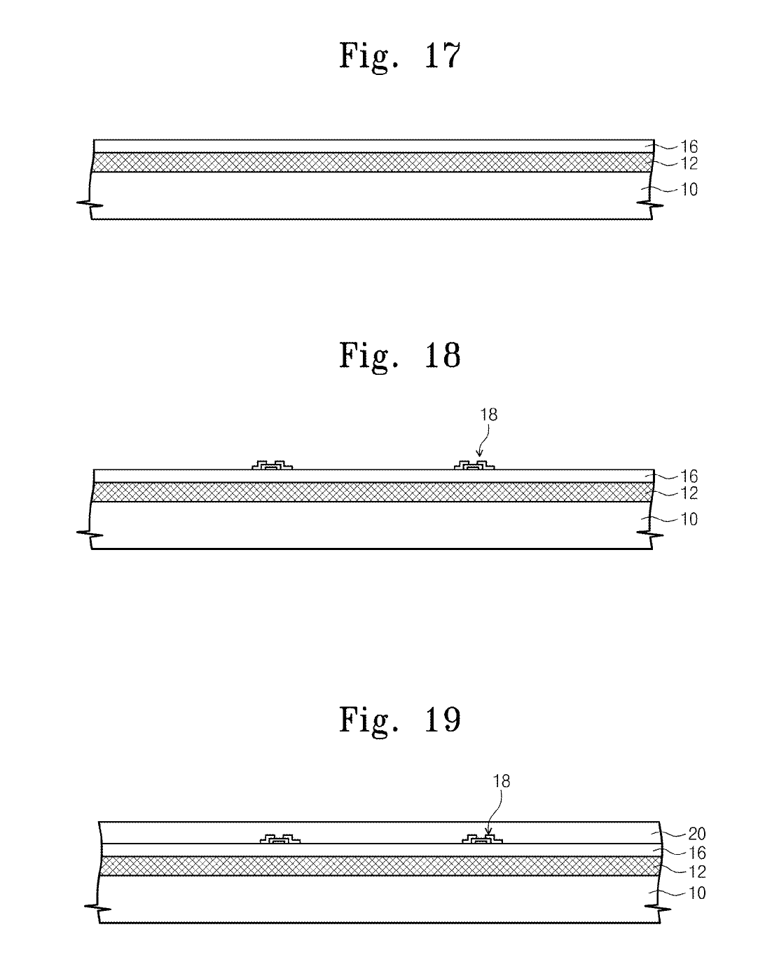

FIGS. 17 through 25 are sectional views illustrating a method of fabricating a reflective liquid crystal display according to the second embodiment of the inventive concept.

Firstly, referring back to FIG. 4, the reflective layer 12 may be formed on the lower substrate 10.

Referring to FIG. 17, the third insulating layer 16 may be formed on the reflective layer 12. The third insulating layer 16 may include a dielectric or polymer layer. The third insulating layer 16 may be formed using a spin-coating method.

Referring to FIG. 18, the thin-film transistors 18 may be formed on the third insulating layer 16.

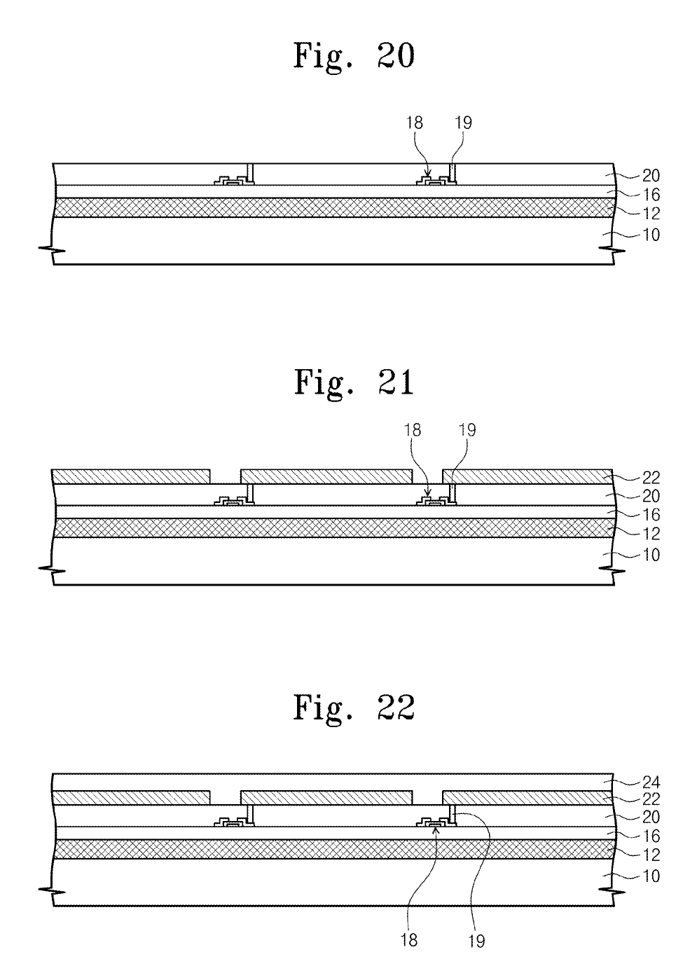

Referring to FIG. 19, the first planarization layer 20 may be formed on the thin-film transistors 18. The first planarization layer 20 may include a polymer and/or resist layer.

The first planarization layer 20 may be formed using a spin-coating process.

Referring to FIG. 20, the first planarization layer 20 may be etched to form a contact hole, and then, the contact electrode 19 may be formed in the contact hole.

Referring to FIG. 21, the lower electrodes 22 may be formed on the first planarization layer 20. The formation of the lower electrodes 22 may include forming an electrode layer on the lower substrate 10 using a sputtering process and patterning the electrode layer to have substantially the same shape as the layer of color filters 14.

Referring to FIG. 22, the first insulating layer 24 may be formed on the lower electrodes 22 and the first planarization layer 20. The first insulating layer 24 may include a transparent organic material or a transparent inorganic material, which may be formed using a spin-coating process or a chemical vapor deposition.

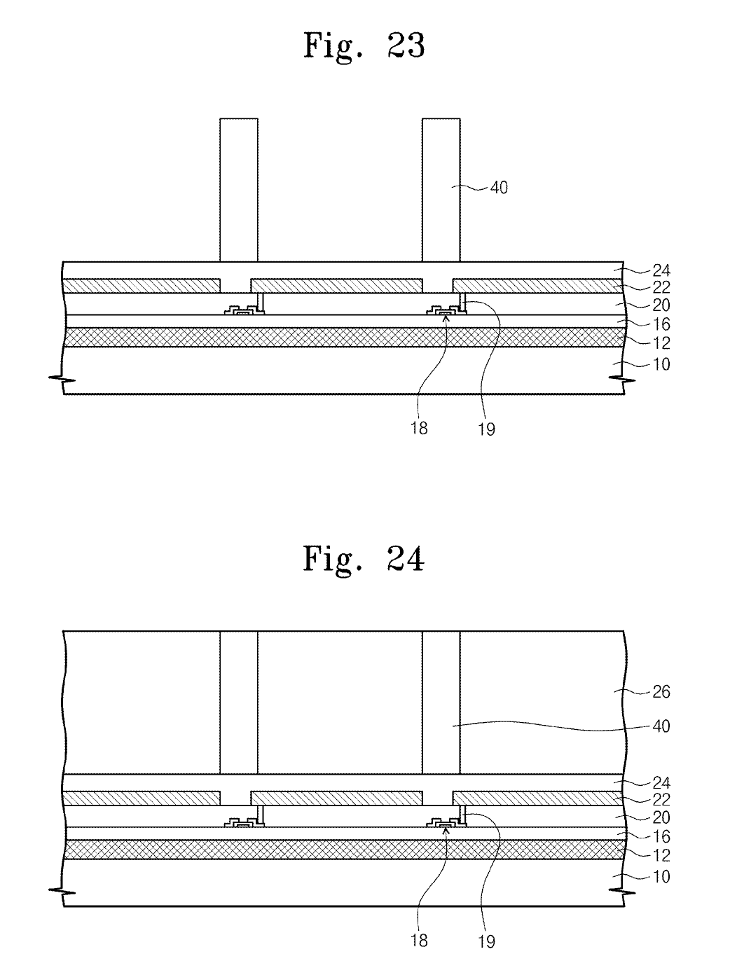

Referring to FIG. 23, the partition walls 40 may be formed on the first insulating layer 24. The partition walls 40 may be formed on the first insulating layer 24 between the lower electrodes 22. In plan view, the partition walls 40 may be formed to surround the layer of color filters 14 or the lower electrodes 22. In other words, the partition walls 40 may be formed to define regions for the sub pixels 42.

Referring back to FIG. 12, the upper electrode 32 may be formed on the upper substrate 30.

Referring back to FIG. 13, the second insulating layer 34 may be formed on the upper electrode 32. The second insulating layer 34 may include the concavo-convex portions 38, which may be formed by an embossing process. For example, the concavo-convex portions 38 may be printed on the top surface of the second insulating layer 34.

Accordingly, in the present embodiment, it is also possible to reduce a cost required to fabricate a panel for the reflective liquid crystal display and to improve fabrication productivity.

Referring to FIG. 24, the liquid crystal layer 26 may be formed on the lower substrate 10 between the partition walls 40. The liquid crystal layer 26 may include different coloring materials, allowing to display different colors from each other.

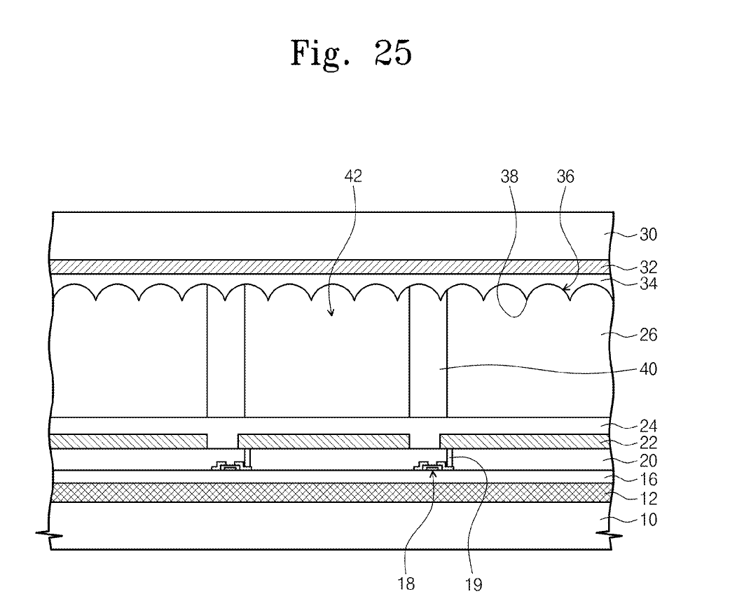

Referring to FIG. 25, the lower and upper substrates 10 and 30 may be fixedly jointed with each other.

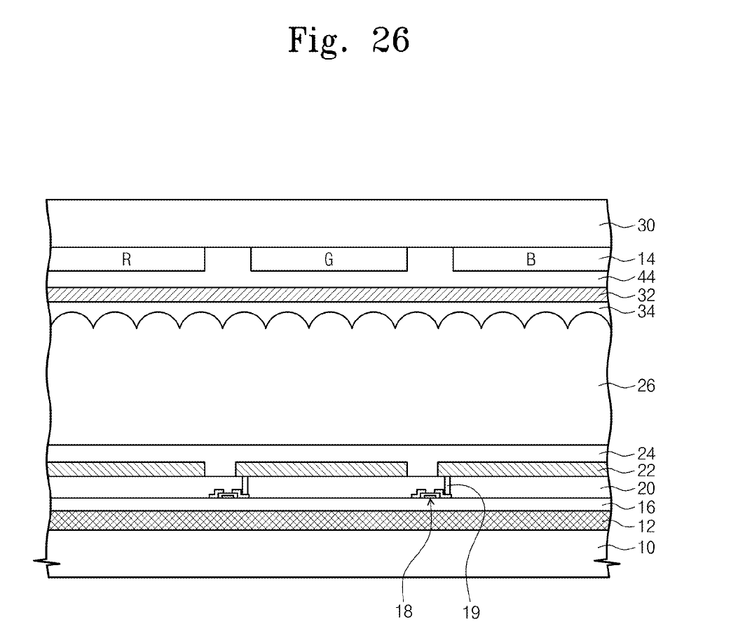

FIG. 26 is a sectional view illustrating a reflective liquid crystal display according to a third embodiment of the inventive concept.

Referring to FIGS. 2, 3 and 26, according to a third embodiment of the inventive concept, a liquid crystal display may be configured in such a way that the layer of color filters 14 and a second planarization layer 44 may be provided the upper substrate 30 to face the first planarization layer 20 on the lower substrate 10.

The layer of color filters 14 may colorize the incident light 50 and/or the reflected light 60. The third embodiment of the inventive concept may differ from the first embodiment described with reference to FIGS. 1 through 15, in that the color filter layer 14 may be disposed on the upper substrate 30.

The second planarization layer 44 may include a transparent organic material and/or a transparent inorganic material. The first and second planarization layers 20 and 44 may enable to maintain uniformly a cell gap between the lower and upper electrodes 22 and 32.

The second insulating layer 34 may be provided on the upper electrode 32. The second insulating layer 34 may include the rough surface 36. The rough surface 36 may contribute to improve linearity of the incident light 50 and the reflected light 60. The incident light 50 may be colorized by the layer of color filters 14. The rough surface 36 may enable to prevent a problem of color mixing from occurring, and thus, it is possible to improve optical efficiency of the reflective liquid crystal display.

A fabricating method of the reflective liquid crystal display, according to the third embodiment of the inventive concept, will be described below.

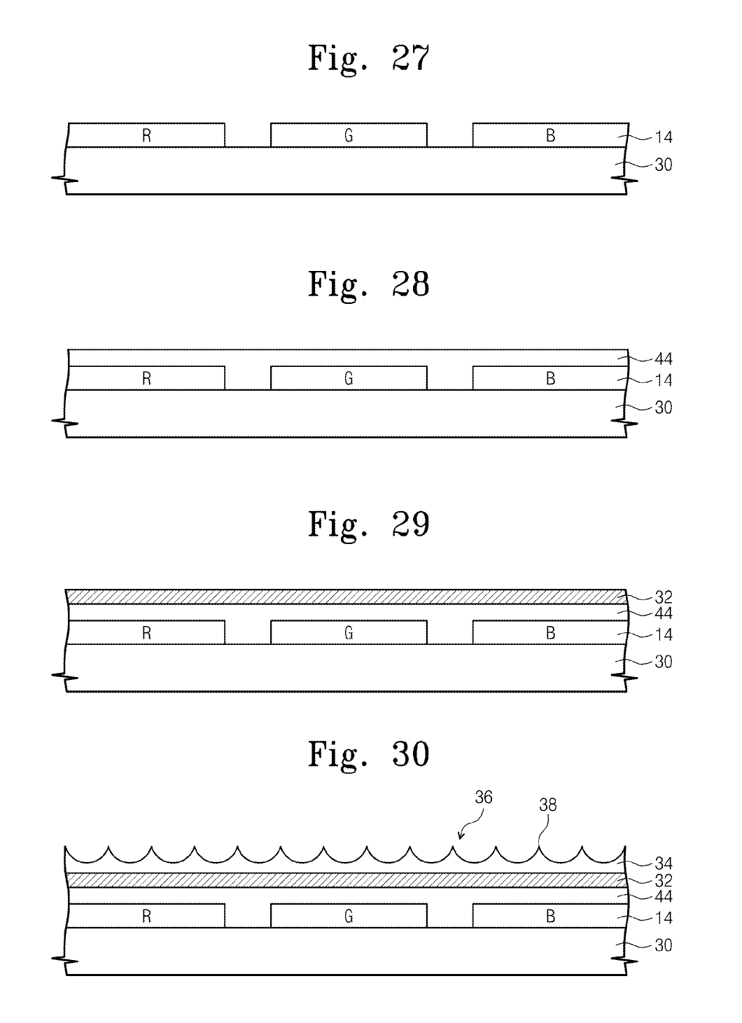

FIGS. 27 through 32 are sectional views illustrating a method of fabricating a reflective liquid crystal display according to the third embodiment of the inventive concept.

Referring back to FIGS. 17 through 22, the first insulating layer 24 may be formed on the lower substrate 10.

Referring to FIG. 27, the layer of color filters 14 may be formed on the upper substrate 30. The layer of color filters 14 may include pigment and/or dye. Same colored ones of the color filters 14 may be formed by a printing process.

Referring to FIG. 28, the second planarization layer 44 may be formed on the layer of color filters 14. The second planarization layer 44 may include a transparent organic material and/or a transparent inorganic material. The second planarization layer 44 may be formed using a spin-coating process or a chemical vapor deposition.

Referring to FIG. 29, the upper electrode 32 may be formed on the second planarization layer 44. The upper electrode 32 may include a transparent metal (e.g., ITO or IZO). The transparent metal may be formed using a sputtering process.

Referring to FIG. 30, the second insulating layer 34 may be formed on the upper electrode 32. The second insulating layer 34 may include the rough surface 36, which may be defined by the concavo-convex portions 38. The concavo-convex portions 38 may be printed on the top surface of the second insulating layer 34 by an embossing process.

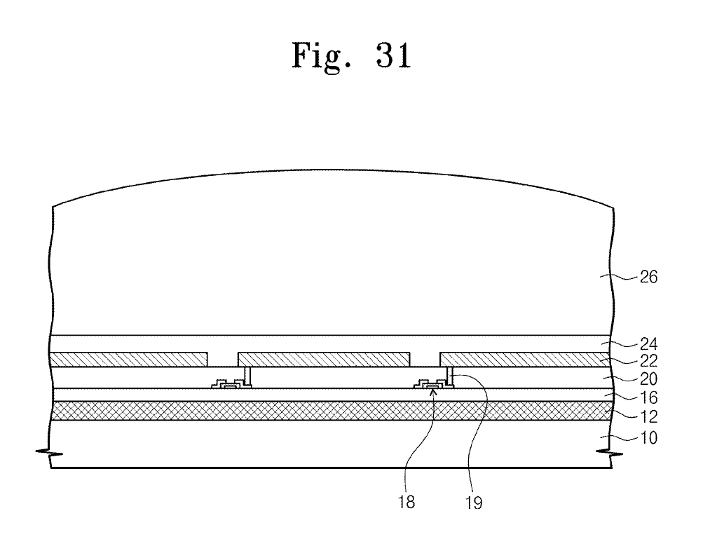

Referring to FIG. 31, the liquid crystal layer 26 may be formed on the first insulating layer 24. The liquid crystal layer 26 may be provided (for example, in a dripping manner) on the lower substrate 10 or the upper substrate 30. In example embodiments, an amount of liquid crystal drips may be controlled during the dripping of the liquid crystal layer 26

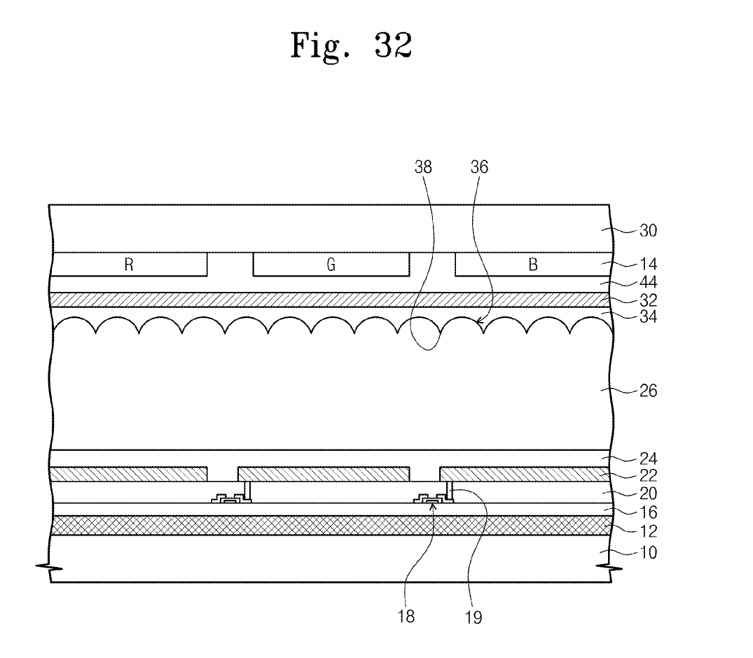

Referring to FIG. 32, the lower and upper substrates 10 and 30 may be fixedly jointed with each other.

According to example embodiments of the inventive concept, a reflective liquid crystal display may include a first substrate, a second substrate facing the first substrate, and a liquid crystal layer between the first and second substrate. A reflective layer and a first insulating layer may be disposed between the liquid crystal layer and the first substrate. A reflective layer may reflect an external light transmitted through the second substrate. That is, a backlight may be replaced with the reflective layer, and thus, it is possible to reduce power consumption.

A second insulating layer may be disposed between the liquid crystal layer and the second substrate. The second insulating layer may have a rough surface. For example, the rough surface may include concavo-convex portions formed in a regular manner to constitute a top surface of the second insulating layer. The concavo-convex portions may increase a refractive index of a reflected light, thereby preventing a problem of color mixing and improving optical efficiency. The concavo-convex portions may be easily formed or printed on the second insulating layer by an engraving roll and/or an engraving sheet. Accordingly, it is possible to reduce a cost required to fabricate a panel for the reflective liquid crystal display and to improve fabrication productivity.

While example embodiments of the inventive concepts have been particularly shown and described, it will be understood by one of ordinary skill in the art that variations in form and detail may be made therein without departing from the spirit and scope of the attached claims.

What is claimed is:

1. A reflective liquid crystal display, comprising:
a first substrate;
a reflective layer on the first substrate;
a first electrodes on the reflective layer;
a first insulating layer on the first electrodes;
a second substrate facing the first substrate;
a second electrode on the second substrate;
a second insulating layer on the second electrode; and
a liquid crystal layer between the first insulating layer and the second insulating layer,
wherein the second insulating layer has concavo-convex portions, which are formed in contact with the liquid crystal layer to improve linearity of an incident light propagating from the second substrate toward the reflective layer and a reflected light propagating from the reflective layer toward the second substrate.

2. The device of claim 1, wherein the concavo-convex portions have a hemi-spherical shape and/or a pyramid shape.

3. The device of claim 1, further comprising color filters provided between the reflective layer and the first electrodes.

4. The device of claim 3, further comprising a first planarization layer provided between the color filters and the first electrodes.

5. The device of claim 4, further comprising third insulating layers provided between the first planarization layer and the reflective layer to separate the color filters from each other.

6. The device of claim 5, further comprising thin-film transistors provided between the third insulating layer and the first planarization layer and connected to the first electrodes via a contact electrode penetrating the first planarization layer.

7. The device of claim 1, further comprising partition walls provided between the first and second insulating layers to divide the liquid crystal layer into a plurality of sub pixels corresponding to the first electrodes.

8. The device of claim 7, wherein each of the sub pixels of the liquid crystal layer contains a coloring material capable of displaying a corresponding one of the three primary colors or the three primary lights.

9. The device of claim 1, further comprising,
color filters between the second electrode and the second substrate; and
a second planarization layer between the color filters and the second electrode.

10. The device of claim 1, wherein the liquid crystal layer contains a black coloring material.

11. A method of fabricating a reflective liquid crystal display, comprising:
forming a reflective layer on a first substrate;
forming a first electrode on the reflective layer;
forming a first insulating layer on the first electrode;
forming a second electrode on a second substrate facing the first substrate;
forming a second insulating layer on the second electrode to have concavo-convex portions;
forming a liquid crystal layer on one of the first and second substrates; and
jointing the first and second substrates.

12. The method of claim 11, wherein the concavo-convex portions are formed using an embossing process.

13. The method of claim 12, wherein the embossing process includes printing the concavo-convex portions with an engraving roll and/or an engraving sheet.

14. The method of claim 11, further comprising,
forming a third insulating layer on the reflective layer;
forming a thin-film transistor on the third insulating layer;
forming a first planarization layer on the thin-film transistor and the third insulating layer;
patterning the first planarization layer to form a contact hole exposing a top surface of the thin-film transistor; and
forming a contact electrode in the contact hole.

15. The method of claim 14, further comprising forming color filters on the reflective layer.

16. The method of claim 14, further comprising forming partition walls on one of the first and second insulating layers between the first electrodes.

17. The method of claim 14, further comprising, before the forming of the second electrode,
forming color filters on the second substrate; and
forming a second planarization layer on the color filters and the second substrate.

18. The method of claim 11, further comprising forming partition walls on the first insulating layer.

19. The method of claim 11, wherein the forming of the liquid crystal layer includes dripping a liquid crystal material between the partition walls.

20. The method of claim 19, wherein the liquid crystal layer contains coloring materials allowing each of sub pixels, which are defined by the first electrodes, to display a corresponding one of the three primary colors or the three primary lights.
